(19) United States
(12) Patent Application Publication
(10) Pub. No.: US 2026/0148366 A1
(43) Pub. Date: May 28, 2026

(54) METHOD AND APPARATUS FOR DETECTING WAFER DEFECTS

(71) Applicant: DONGFANG JINGYUAN ELECTRON LIMITED, SHANGHAI (CN)

(72) Inventors: Hao YU, SHANGHAI (CN); Rongjia ZHANG, SHANGHAI (CN); Nuo DING, SHANGHAI (CN); Yuan GAN, SHANGHAI (CN); Changlian YAN, SHANGHAI (CN); Chunying HAN, SHANGHAI (CN)

(73) Assignee: DONGFANG JINGYUAN ELECTRON LIMITED, SHANGHAI (CN)

(21) Appl. No.: 19/123,068

(22) PCT Filed: Aug. 23, 2024
(86) PCT No.: PCT/CN2024/114327

§ 371 Date: Apr. 22, 2025

(30) Foreign Application Priority Data
Sep. 13, 2023 (CN) 202311186973.4

(51) Int. Cl. G06T 7/00; G01N 23/2251; G06T 7/12

(52) U.S. Cl. CPC G06T 7/0006; G01N 23/2251; G06T 7/001; G06T 7/12; G01N 2223/401; G01N 2223/6116; G01N 2223/646; G06T 2207/10061; G06T 2207/30148

(57) ABSTRACT

Disclosed in the present application are a method and apparatus for detecting wafer defects which relates to the field of semiconductor. The method provided by the present application comprises: determining a repeating pattern unit and a non-repeating pattern unit in a Scanning Electron Microscope (SEM) image based on a SEM image to be detected and pattern units in a design layout; measuring the pattern units in the design layout, the repeating pattern unit, and the non-repeating pattern unit to determine difference information; and determining whether the repeating pattern unit and the non-repeating pattern unit have defects based on the difference information.

### CROSS-REFERENCE TO RELATED APPLICATION

The present application is a National Stage of International Application No. PCT/CN 2024/114327 filed on Aug. 23, 2024, which claims priority to Chinese Patent Application No. 202311186973.4, filed on Sep. 13, 2023, entitled “METHOD AND APPARATUS FOR DETECTING WAFER DEFECTS”, and submitted to China Patent Office, both of which are hereby incorporated by reference in their entireties.

### TECHNICAL FIELD

The present application relates to the field of semiconductor technology, and particularly, to a method and apparatus for detecting wafer defects.

### BACKGROUND

With the development of the semiconductor industry, the application of integrated circuits is becoming more and more widespread. Since a plurality of processes are involved in the integrated circuit production process, the wafer may be contaminated in each process, so it is necessary to detect the defects in the wafer production process.

In the related art, when defect detection is performed on a wafer, a certain threshold value is usually set, and when the degree of difference between a wafer to be detected and a reference wafer exceeds the threshold value, it is determined that the wafer has a defect. However, because the threshold value is a fixed value, when the image to be detected is relatively complex, miss-detection and false-detection may occur, thus affecting the accuracy of wafer defect detection. Therefore, how to improve the accuracy of wafer defect detection is very important.

### SUMMARY

Embodiments of the present application is to provide a method and apparatus for detecting wafer defects.

In a first aspect, embodiments of the present application provides a method and apparatus for detecting wafer defects, comprising: determining a repeating pattern unit and a non-repeating pattern unit in a Scanning Electron Microscope (SEM) image based on the SEM image to be detected and pattern units in a design layout; measuring the pattern units in the design layout, the repeating pattern unit, and the non-repeating pattern unit to determine difference information; and determining whether the repeating pattern unit and the non-repeating pattern unit have defects based on the difference information.

In some embodiments, the determining a repeating pattern unit and a non-repeating pattern unit in a SEM image based on a SEM image to be detected and the pattern units in a design layout comprises: processing the SEM image to obtain pattern outlines in the SEM image; and matching the pattern outlines with the pattern units in the design layout to determine the repeating pattern unit and the non-repeating pattern unit in the SEM image.

In some embodiments, the measuring the pattern units in the design layout, the repeating pattern unit, and the non-repeating pattern unit to determine difference information comprises: segmenting the non-repeating pattern unit to obtain a repeating pattern sub-unit and an isolated pattern sub-unit; setting measurement points in the repeating pattern unit and the repeating pattern sub-unit to determine first measurement data; setting the measurement points in corresponding the target pattern units of the design layout at the same positions to determine second measurement data; and determining the difference information based on the first measurement data and the second measurement data.

In some embodiments, the determining the difference information based on the first measurement data and the second measurement data comprises: determining the difference information corresponding to each of measurement types based on the measurement type of the first measurement data and the measurement type of the second measurement data.

In some embodiments, the determining whether the repeating pattern unit and the non-repeating pattern unit have defects based on the difference information comprises: determining a mean value and a standard deviation corresponding to each of the measurement type based on the measurement type of the first measurement data and the measurement type of the second measurement data corresponding to the difference information; and determining whether the repeating pattern unit or the repeating pattern sub-unit has a defect based on each of the first measurement data, the mean value, and the standard deviation corresponding to the measurement type.

In some embodiments, the determining whether the repeating pattern unit or the repeating pattern sub-unit has a defect based on each of the first measurement data, the mean value, and the standard deviation corresponding to the measurement type comprises: determining the measurement threshold value corresponding to the measurement type based on the mean value and standard deviation corresponding to the measurement type; in response to any one of the first measurement data being greater than the measurement threshold value of the measurement type, determining that the repeating pattern unit or the repeating pattern sub-unit where the first measurement data being greater than the measurement threshold value of the measurement type is located has the defect; and determining the repeating pattern unit or the repeating pattern sub-unit where any one of the first measurement data being greater than the measurement threshold value of the measurement type is located to be an abnormal pattern unit, and storing the abnormal pattern unit and any one of the first measurement data in an abnormal feature library.

In some embodiments, the determining whether the repeating pattern unit and the non-repeating pattern unit have defects based on the difference information comprises matching the isolated pattern sub-unit with an abnormal pattern unit in the abnormal feature library to determine a degree of matching, and determining whether the isolated pattern sub-unit has a defect based on the degree of matching.

In a second aspect, embodiments in the present application provides an apparatus for detecting wafer defects, comprising: a first determination module configured to determine a repeating pattern unit and a non-repeating pattern unit in a SEM image based on the SEM image to be detected and pattern units in the design layout; a measurement module configured to measure pattern units in the design layout, the repeating pattern unit, and the non-repeating pattern unit to determine difference information; a second determining module configured to determine whether the repeating pattern unit and the non-repeating pattern unit have defects based on the difference information.

In some embodiments, the first determination module is specifically configured to process the SEM image to obtain a pattern outlines in the SEM image, and to match the pattern outlines with the pattern units in the design layout to determine repeating pattern units and non-repeating pattern units in the SEM image.

In some embodiments, the measurement module includes: a segmentation sub-module configured to segment the non-repeating pattern unit to obtain a repeating pattern sub-unit and an isolated pattern unit; a first determination sub-module configured to set measurement points in the repeating pattern unit and the repeating pattern sub-unit to determine first measurement data; a second determination sub-module configured to set the measurement points at the same position of the target pattern unit corresponding to the design layout to determine second measurement data; a third determination sub-module configured to determine difference information based on the first measurement data and the second measurement data.

In some embodiments, the third determination sub-module is configured to determine the difference information corresponding to each of the measurement types based on the measurement type of the first measurement data and the measurement type of the second measurement data.

In some embodiments, the second determination module includes: a fourth determination sub-module configured to determine a mean value and a standard deviation corresponding to the measurement type based on the measurement types of the first measurement data and the second measurement data corresponding to the difference information; a fifth determination sub-module configured to determine whether the repeating pattern unit or the repeating pattern sub-unit has a defect based on each of the first measurement data corresponding to the measurement type, a corresponding mean value and a corresponding standard deviation.

In some embodiments, the fifth determining sub-module includes: a first determination unit configured to determine a measurement threshold value corresponding to the measurement type based on a mean value and a standard deviation corresponding to the measurement type; a second determination unit configured to determine that the repeating pattern unit or the repeating pattern sub-unit where any one of the first measurement data is located has a defect when any one of the first measurement data is greater than a measurement threshold value of the measurement type; a third determination unit configured to determine a repeating pattern unit or a repeating pattern sub-unit where any one of the first measurement data is located as an abnormal pattern unit, and to store the abnormal pattern units and the any one of the first measurement data into the abnormal feature library.

In some embodiments, the second determination module is specifically configured to match the isolated pattern unit with an abnormal pattern unit in an abnormal feature library to determine a degree of matching, and determine whether the isolated pattern sub-unit has a defect based on the degree of matching.

In a third aspect, embodiments in the present application provides electronic device comprising a processor; and a memory in which computer program instructions are stored, where the processor implements the above method for detecting wafer defects when executing computer program instructions.

In a fourth aspect, embodiments in the present application provides electronic device comprising computer-readable storage medium, storing computer program instructions which implement the method for detecting wafer defects when executed by a processor.

In summary, the method and apparatus for detecting wafer defects provided by embodiments in the present application have at least the following beneficial effects: the repeating pattern unit and the non-repeating pattern unit in the SEM image may be determined based on the pattern unit in the SEM image to be detected and the design layout, and then the pattern unit, the repeating pattern unit, and the non-repeating pattern unit in the design layout may be measured to determine difference information, and whether the repeating pattern unit and the non-repeating pattern unit have defects may be determined based on the difference information. Therefore, in the process of wafer defect detection, the SEM image and the pattern units in the design layout can be measured to obtain the difference information which can characterize the SEM image, and then the SEM image is detected based on the difference information. Since the characteristics of the SEM image and the pattern elements in the design layout are fully considered in the process of defect detection, the determined difference information can be made more comprehensive and reliable, and the accuracy and reliability of the subsequent wafer defect detection are improved.

### BRIEF DESCRIPTION OF THE DRAWINGS

Accompanying drawings described herein are used for a further understanding of the present application and constitute a part of the present application. Illustrative embodiments of the present application and illustration thereof are used for explaining the present application and do not improperly limit the present application. In the accompanying drawings:

FIG. 1 is a flowchart of a method for detecting wafer defects according to an embodiment of the present application;

FIG. 2 is a schematic view of a design layout and SEM image to be detected according to an embodiment of the present application;

FIG. 3 is a flowchart of a method for detecting wafer defects according to an embodiment of the present application;

FIG. 4 is a schematic view of a SEM image to be detected provided after segmentation according to an embodiment of the present application;

FIG. 5 is a structural view of an apparatus for detecting wafer defects according to an embodiment of the present application; and

FIG. 6 is a structural view of an electronic device according to an embodiment of the present application.

### DETAILED DESCRIPTION

To further clarify the above and other features and advantages of the present invention, a more particular description of the invention will be rendered by reference to specific embodiments thereof which are illustrated in the appended drawings. It should be understood that the specific embodiments presented herein are for purposes of explanation to those skilled in the art, are exemplary only, and are not intended to be limiting.

In the following description, numerous specific details are set forth in order to provide a thorough understanding of the present application. It will be apparent, however, to one skilled in the art that the specific details need not be employed to practice the present application. In other instances, well-known steps or operations have not been described in detail in order not to obscure the present application.

The method for detecting a wafer defect according to an embodiment of the present application can be performed by an apparatus for detecting wafer defects according to an embodiment of the present application, which can be configured in an electronic device.

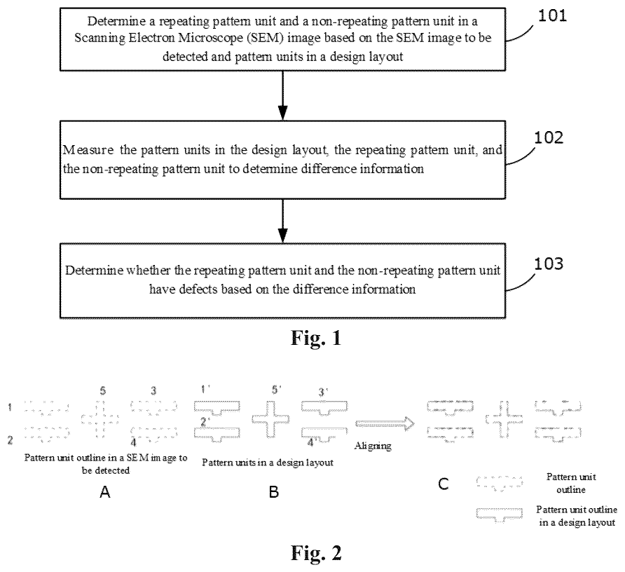

Referring to FIG. 1, the present application provides a method for detecting wafer defects including steps 101, 102, and 103.

In step 101, a repeating pattern unit and a non-repeating pattern unit in a SEM (Scanning Electron Microscope) image are determined based on the SEM image to be detected and pattern units in the design layout.

The scanning electron microscope image, i.e., the SEM image, is an image by acquiring secondary electrons, backscattered electrons, etc. generated from the interaction between electrons and a wafer as a result of bombarding the wafer surface with a finely focused electron beam, and can be used for defect detection and analysis of the wafer.

It can be understood that, generally, for a wafer to be detected, a SEM image thereof can be acquired first, then a design layout corresponding to the wafer to be detected can be acquired, and then a repeating pattern unit and a non-repeating pattern unit in the SEM image can be determined by aligning and matching the SEM image with corresponding pattern units in the design layout.

In the case where the SEM image of the wafer to be detected is aligned with the design layout, if a certain pattern unit 1 in the SEM image of the wafer to be detected matches multiple pattern units in the design layout, it can be determined that the pattern unit 1 is a repeating pattern unit. Alternatively, in the case where a certain pattern unit 2 appears multiple times in the design layout, if a pattern unit 3 in the SEM image matches the pattern unit 2 appearing multiple times in the design layout, it can be determined that the pattern unit 3 is a repeating pattern unit. Alternatively, if a certain pattern unit 4 appears only once in the design layout, a pattern unit 5 corresponding to that pattern unit 4 in the SEM image can be determined to be a non-repeating pattern unit.

It is to be understood that the number of repeating pattern units in the SEM image may be one, or may be multiple, or may be zero. The number of non-repeating pattern units may also be zero, one, or multiple, etc., which is not limited in the present application.

Optionally, the SEM image may be processed to obtain pattern outlines in the SEM image, and then the pattern outlines are matched with the pattern units in the design layout to determine the repeating pattern unit and the non-repeating pattern unit in the SEM image.

The SEM image can be processed in any desirable manner. For example, the SEM image can be processed by means of image extraction, outline extraction, etc. to obtain pattern outlines in the SEM image; then each pattern outline in the SEM image is aligned with each pattern unit in the design layout according to, for example, position coordinates, a central point, etc. ; matching is performed, and then the repeating pattern unit and the non-repeating pattern unit in the SEM image are determined according to the matching result.

For example, the pattern outlines are obtained as shown in FIG. 2(A) after the SEM image is processed, and the pattern units in the design layout are as shown in FIG. 2(B); then the pattern outlines and the pattern units in the design layout are aligned, and the schematic view of the pattern outlines and the pattern units in the design layout that are aligned can be as shown in FIG. 2(C); since the pattern units 1′, 2′, 3′, and 4′in the design layout are the same pattern which appears repeatedly, then the pattern units 1, 2, 3, and 4 in the SEM image corresponding thereto are repeating pattern units, and since the pattern unit 5′in the design layout appears only once, then the pattern unit 5 in the SEM image is a non-repeating pattern unit.

It should be noted that the above-mentioned examples are merely illustrative, and should not be construed as a limit for the shape, number, position, etc. of the repeating pattern unit and the non-repeating pattern unit in the embodiments of the present application.

In step 102, the pattern units in the design layout, the repeating pattern unit, and the non-repeating pattern unit are measured to determine difference information.

The non-repeating pattern unit may be a complex pattern unit, and in embodiments of the present application, the non-repeating pattern unit may be segmented to obtain corresponding repeating pattern sub-units and an isolated pattern sub-unit. The number of segmented repeating pattern sub-units may be one, or may be multiple, zero, etc., and the number of isolated pattern sub-units may be one, or zero, multiple, etc., which is not limited in the present application.

For example, after a non-repeating pattern unit is segmented, four identical rectangular patterns and an irregular pattern are obtained, and then the four identical rectangular patterns are repeating pattern sub-units, and the irregular pattern is an isolated pattern sub-unit, etc.

It should be noted that the above examples are illustrative only and should not be construed as a limit for the shape, number, position, etc. of the repeating pattern sub-units and the isolated pattern sub-units in the embodiments of the present application.

The repeating pattern unit and the corresponding target pattern unit in the design layout are measured after the repeating pattern unit and the non-repeating pattern unit in the SEM image are determined, and the difference information corresponding to the repeating pattern unit is determined according to the measurement result. The non-repeating pattern unit can then be segmented to obtain the repeating pattern sub-units and the isolated pattern sub-unit of the segmented non-repeating pattern unit, and measurement is performed on the repeating pattern sub-units and the target pattern unit in the design layout, and difference information of the repeating pattern sub-units is determined according to the measurement result.

In addition, the difference information can be understood as a difference, a ratio, etc. between the measurement results of the repeating pattern units and the corresponding target pattern unit in the design layout, and a difference, a ratio, etc. between the measurement results of the repeating pattern sub-unit and the corresponding target pattern unit in the design layout. The difference information may be used to characterize the degree of difference between the repeating pattern unit and the target pattern unit in the design layout, and the degree of difference between the non-repeating pattern unit and the target pattern unit in the design layout, and may include one difference data, or may also include a plurality of difference data, etc., which are not limited in this application.

Accordingly, in embodiments of the present application, it is possible to determine the difference information according to the measurement results by measuring the repeating pattern unit, the non-repeating pattern unit, and the pattern units in the design layout. Since the pattern units in the design layout and the pattern units in the SEM image are fully taken into account in determining the difference information, the difference information can be more comprehensive and reliable to better reflect the characteristics of the SEM image, and then the comprehensive and reliable difference information is used to provide conditions for the subsequent wafer defect detection.

In step 103, whether there is a defect in the repeating pattern unit and the non-repeating pattern unit is determined based on the difference information.

It will be appreciated that since the difference information can be configured to characterize the degree of difference between the repeating pattern unit and the target pattern unit in the design layout, as well as the degree of difference between the non-repeating pattern unit and the target pattern unit in the design layout. Thus, the more significant the difference information, and the higher the likelihood of defects in the repeating pattern unit and the non-repeating pattern unit. The less the difference information, the lower the likelihood of defects in the repeating pattern unit and the non-repeating pattern unit.

For example, if the difference value between a repeating pattern unit and the corresponding target pattern unit in the design layout is “0”, then the repeating pattern unit can be considered to be identical to the corresponding target pattern unit in the design layout, and the repeating unit has no defects. If the difference value between a certain repeating pattern unit and the corresponding target pattern unit in the design layout is “1”, it can be considered that the repeating pattern unit is inconsistent with the corresponding target pattern unit in the design layout, and the repeating unit has a defect.

It should be noted that the above-mentioned examples are merely illustrative and should not be construed as a limit for the manner of determining whether or not the repeating pattern unit and the non-repeating pattern unit have defects in the embodiments of the present application.

Accordingly, in the embodiments of the present application, the difference information can be determined by measuring the pattern units in the design layout, the repeating pattern unit, and the non-repeating pattern unit, and whether there is a defect in the repeating pattern unit and the non-repeating pattern unit is determined on the basis of the difference information. That is to say, in the process of determining the difference information, the SEM image and the pattern units in the design layout are fully taken into account, so that the determined difference information can be more comprehensive and reliable and can better reflect the characteristics of the SEM image. Then the defect detection is performed on a wafer using the comprehensive and reliable difference information. The accuracy is also higher and more reliable.

In an embodiment of the present application, a repeating pattern unit and a non-repeating pattern unit in the SEM image can be determined based on the SEM image to be detected and pattern units in the design layout, a measurement can be performed on the pattern units, the repeating pattern units, and the non-repeating pattern units in the design layout to determine difference information, and whether the repeating pattern units and the non-repeating pattern units have defects is determined based on the difference information. Therefore, in the process of wafer defect detection, the SEM image and the pattern units in the design layout can be measured to obtain the difference information which can characterize the SEM image, and then defect detection is performed on the SEM image based on the difference information. Since the characteristics of the SEM image and the pattern units in the design layout are fully considered in the process of defect detection, the determined difference information can be made more comprehensive and reliable, and the accuracy and reliability of the subsequent wafer defect detection are improved.

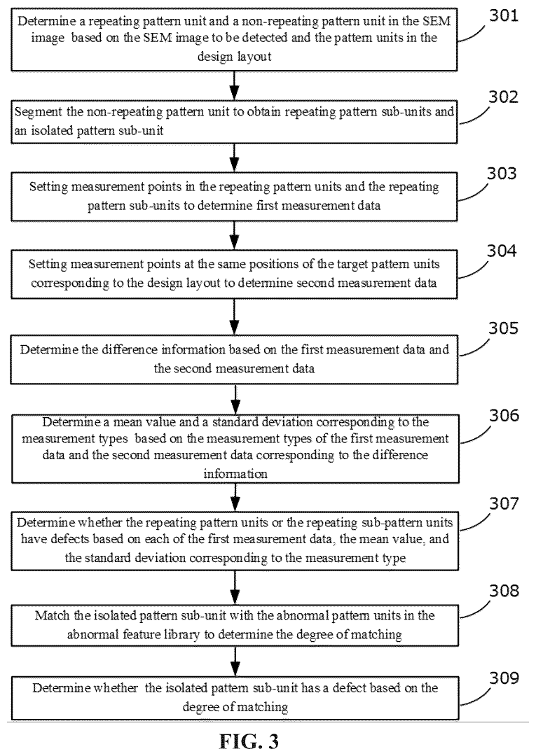

As shown in FIG. 3, the method for detecting wafer defects may include the following steps 301, 302, and 303.

In step 301, a repeating pattern unit and a non-repeating pattern unit in the SEM image are determined based on the SEM image to be detected and the pattern units in the design layout.

In step 302, the non-repeating pattern unit is segmented to obtain repeating pattern sub-units and an isolated pattern sub-unit.

The non-repeating pattern unit may be segmented in any desirable manner to obtain repeating pattern sub-units and an isolated pattern sub-unit. For example, a pattern sub-unit such as a line width pattern sub-unit and a line terminal pattern sub-unit can be obtained by segmenting a non-repeating pattern unit in the manner of a line width and a line terminal, etc. If a certain pattern sub-unit appears multiple times, that is to say, there are multiple pattern sub-units, then the pattern sub-units can be determined as repeating pattern sub-units. If a certain pattern sub-unit appears only once, that is to say, there is such one pattern sub-unit, then the pattern sub-unit can be determined as an isolated pattern sub-unit, etc., which is not limited in the present application.

In step 303, measurement points are set in the repeating pattern unit and the repeating pattern sub-unit to determine first measurement data.

There may be one or more measurement points, and there may be one or more types of the measurement points, etc., which are not limited in this application.

With regard to the same type of repeating pattern units and repeating pattern sub-units, measurement points can be set according to the same rule to measure the repeating pattern units and the repeating pattern sub-units and to obtain first measurement data corresponding to the repeating pattern units and first measurement data corresponding to the repeating pattern sub-units, etc., which is not limited in the present application.

Alternatively, the non-repeating pattern unit may be segmented by line width, line terminal, etc., to obtain repeating pattern sub-units and the isolated pattern sub-unit, and then a detection frame may be provided in each of the repeating pattern sub-units. For example, a corresponding detection frame, etc., may be provided based on the position, feature, etc., of each of the repeating pattern sub-units, which is not limited in the present application.

It can be understood that for each of the repeating pattern units and each of the repeating pattern sub-units, there may be one or more detection frames provided therein, etc., and the number and type of detection frames provided therein are not limited in the present application.

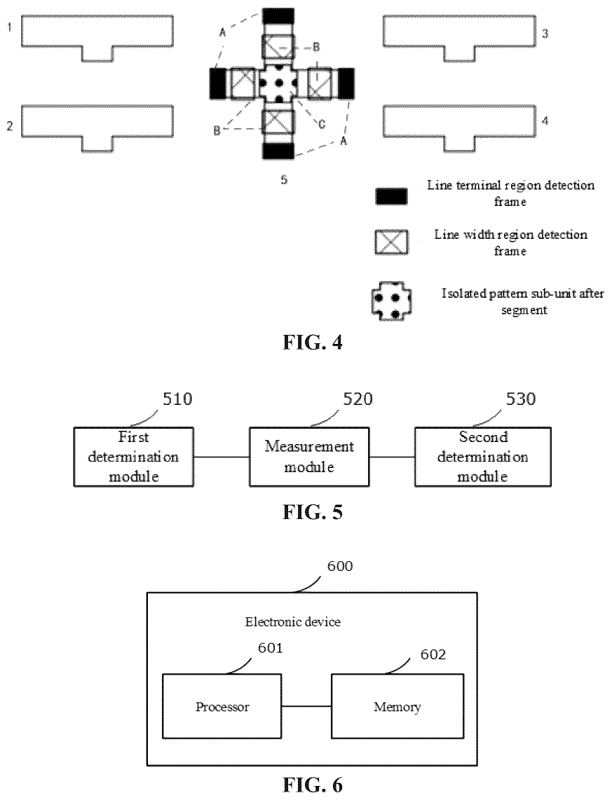

For example, in the schematic view shown in FIG. 4, the pattern units 1, 2, 3 and 4 in FIG. 4 are repeating pattern units, and the pattern unit 5 is a non-repeating pattern unit. The non-repeating pattern unit can be segmented to obtain repeating pattern sub-units, such as line width pattern sub-units, and line terminal pattern units, and an isolated pattern sub-unit. The corresponding detection frames are placed at the repeating pattern sub-units; for example, line width region detection frames are provided at the line width pattern sub-unit, and line terminal region detection frames are provided at the line terminal pattern unit, etc. As shown in FIG. 4, the line terminal region detection frames are provided at the black shaded region A that is the repeating pattern sub-unit 1, the line width region detection frames are provided at the cross-line region B that is the repeating pattern sub-unit 2, and an irregular region C is an isolated pattern sub-unit.

Thereafter, measurement points may be set at intervals of n1um in the black shaded regions A, i.e., the repeating pattern sub-units 1, to measure the repeating pattern sub-units corresponding to the black shaded regions A and to obtain first measurement data corresponding to the line terminal type. Thereafter, measurement points may be set at intervals of n2um within the intersection line regions B, i.e., the repeating pattern sub-unit 2, so as to measure the corresponding repeating pattern sub-units at the intersection line regions B to obtain first measurement data corresponding to the line width type.

In embodiments of the present application, n1 and n2 may be the same, or may be different, etc., and this is not limited in the present application.

It is to be understood that the region corresponding to the measurement points may have the repeating pattern unit outline, the repeating pattern sub-unit outline, or may not have any pattern unit outlines, etc., which is not limited in the present application.

It should be noted that the above examples are merely illustrative and should not be construed as a limit for the manner in which the repeating pattern sub-units, the isolated pattern sub-unit, and the first measurement data are determined in the embodiments of the present application.

In step 304, measurement points are set at the same positions of the target pattern units corresponding to the design layout to determine second measurement data.

In embodiments of the present application, after the measurement points are set in the repeating pattern units and the repeating pattern sub-units, the same measurement points can be respectively set at the same position in the target pattern unit corresponding to the repeating pattern units and the target pattern unit corresponding to the repeating pattern sub-units in the design layout according to corresponding rules, so as to measure each of the target pattern units to obtain corresponding second measurement data.

For example, if measurement points are set at an interval of n1 um within the repeating pattern sub-unit 1, the measurement points may be set at the same position in the target pattern unit 1 in the design layout corresponding to the repeating pattern sub-unit 1; for example, the measurement points may be set at an interval of n1 um to measure the target pattern unit 1 to obtain the second measurement data corresponding to the line terminal type. If the measurement points are set at intervals of n2 um within the repeating pattern sub-unit 2, the measurement points may be set at the same position in the target pattern unit 2 of the design layout corresponding to the repeating pattern sub-unit 2. For example, the measurement points may be set at intervals of n2 um to measure the target pattern unit 2 to obtain the second measurement data corresponding to the line width type.

It is to be understood that the region corresponding to the measurement points may have the repeating pattern unit outline, the repeating pattern sub-unit outline, or not have any pattern unit outlines, etc., which is not limited in the present application.

In embodiments of the present application, n1 and n2 may be the same or may be different, the target pattern unit 1 and the target pattern unit 2 may be the same or may be different, etc., and this is not limited in the present application.

In step 305, difference information is determined based on the first measurement data and the second measurement data.

It can be understood that after the repeating pattern units and the repeating pattern sub-units are measured to obtain corresponding first measurement data, and the target pattern unit in a design layout is measured according to the same measurement method to obtain corresponding second measurement data, the difference information of the repeating pattern unit where each of measurement points is located with respect to the target pattern units in the design layout, difference information of the repeating pattern sub-unit where each of the measurement points is located with respect to the target pattern unit in the design layout, etc. can be determined, and this is not limited in the present application.

Alternatively, the difference information corresponding to each of the measurement types may be determined based on the measurement type of the first measurement data and the measurement type of the second measurement data. There are multiple measurement types. For example, the measurement types may be line width type, line terminal type, etc. or may be divided into line width 1 type, line width 2 type, line width 3 type, etc. according to specific values, which is not limited in the present application.

In addition, the difference information can be understood as difference data. For example, the difference data between the pattern unit in the SEM image and the pattern unit in the design layout may be a difference value, a ratio value, etc. which is not limited in this application.

Take for example that the line width 1 type corresponds to the interval of n1. If the measurement points 1, 2, and 3 are set according to the interval of n1 um in the repeating pattern sub-unit 1, the same measurement points 1′, 2′, and 3′ are set according to the interval of n1 um in the target pattern unit 1′ in the design layout corresponding to the repeating pattern sub-unit 1. If there is no pattern outlines at the measurement point 2, then ⅓ can be determined as the difference information of the missing-outline detection corresponding to the line width 1. If the first measurement data corresponding to the measurement point 1 and the measurement point 3 are both 5 um, the second measurement data corresponding to measurement point 1′ and measurement point 3′are respectively 4.9 um and 5 um, the difference between the first measurement data and the second measurement data corresponding to measurement point 1 and measurement point 3 is respectively: 0.1, 0, and then 0.1 and 0 can be determined as the difference information of the outline change detection corresponding to the line width 1.

It should be noted that the above-mentioned examples are merely illustrative and should not be construed as a limit for the manner in which the difference information is determined in the embodiments of the present application.

Alternatively, since there are one or more detection frames provided in each of the repeating pattern units and each of the repeating pattern sub-units, the difference value corresponding to each of the detection frames may be determined, or the difference value corresponding to a single repeating pattern sub-unit or a single repeating pattern unit may be determined when determining the difference information of the missing-outline detection. For example, in the repeating pattern sub-unit 3, there are three detection frames in total, and there are five measurement points in each of the detection frames; the number of measurement points in each of the detection frames where a pattern outline does not exist is 1, 0, and 3. Then, for each of the detection frames, the difference data of the corresponding missing-outline detection are respectively: ⅕, 0, and ⅗, and for the repeating pattern sub-unit 3, the difference data of the corresponding missing-outline detection is 4/15.

It should be noted that the above-mentioned examples are merely illustrative and should not be construed as a limit for the manner in which the difference information actually detected by the outlines is determined in embodiments of the present application.

It can be understood that, for each of the measurement types, the difference information of the missing-outline detection and the difference information of the outline change detection of each of the measurement types can be respectively determined, and the relevant implementation method can be referred to in the description of the various embodiments of the present application, which will not be described in detail herein.

Alternatively, each of the repeating pattern units and each of the repeating pattern sub-units may be provided with one type of detection frame, or may be provided with multiple types of detection frames, etc. and then the detection points may be set in each of the detection frames according to a certain rule to measure each of the repeating pattern units and each of the repeating pattern sub-units.

In step 306, a mean value and a standard deviation corresponding to the measurement types are determined based on the measurement types of the first measurement data and the second measurement data corresponding to the difference information.

For example, if the difference information of missing-outline detection corresponding to line width 1 is ⅓, ⅔, ⅓, and ⅔, it can be determined that the corresponding mean value is ½, and the standard deviation is ⅙. If the difference information of the outline change detection corresponding to line width 1 is 0.1, 0, 0, and 0.1, it can be determined that the corresponding mean value is 0.05, and the standard deviation is 0.05.

Accordingly, the mean value and standard deviation of the missing-outline detection and the mean value and standard deviation of the outline change detection corresponding to different line widths can be determined in the same manner. It is also possible to determine the mean value and standard deviation of the missing-outline detection and the mean value and standard deviation of the outline change detection corresponding to different line terminals to determine the mean value and standard deviation corresponding to each of the measurement types.

It should be noted that the above-mentioned examples are merely illustrative, and are not intended to limit the manner of determining the mean value and standard deviation corresponding to the measurement type in embodiments of the present application, etc.

In step 307, whether the repeating pattern units or the repeating pattern sub-units have defects is determined based on each of the first measurement data, the mean value, and the standard deviation corresponding to the measurement types.

Alternatively, the measurement threshold value corresponding to the measurement type may be determined based on the mean value and standard deviation corresponding to the measurement type, and then it may be determined that the repeating pattern unit or the repeating pattern sub-unit where any one of the first measurement data is located has a defect if any one of the first measurement data is greater than the measurement threshold value of the measurement type, and then the repeating pattern unit or the repeating pattern sub-unit where any one of the first measurement data is located may be determined to be an abnormal pattern unit, and the abnormal pattern unit and any one of the first measurement data may be stored in the abnormal feature library.

The measurement threshold is not a pre-set and fixed value, for example, the measurement thresholds corresponding to each of measurement types can be determined based on the relationship satisfied by the mean value and standard deviation corresponding to each of the measurement types.

In addition, the abnormal feature library may include an abnormal pattern unit, or may also include measurement data in each of the abnormal patterns, etc. or both may be included therein, etc. which is not limited in the present application.

For example, if the number of the first measurement data in the outline change detection corresponding to the measurement type of the line width 1 is n, the mean value thereof is V¹ₘₑₐₙ, and the standard deviation thereof is V¹_{std}, it can be determined that the measurement threshold value 1 corresponding to the measurement type of the line width 1 is: V¹ₘₑₐₙ+n*V¹_{std}. If the first measurement data 1 corresponding to the measurement type of the current line width 1 is less than the measurement threshold 1, it can be determined that the first measurement data does not have a defect. If the first measurement data 2 corresponding to the measurement type of the current line width 1 is greater than the measurement threshold 1, it can be determined that the repeating pattern unit or the repeating pattern sub-unit where the first measurement data 2 is located is determined to be an abnormal pattern unit, and the abnormal pattern unit and the first measurement data 2 are stored in an abnormal feature library.

For example, if the number of the first measurement data in the missing-outline detection corresponding to the measurement type of the line width 1 is m, the mean value thereof is, and the standard deviation thereof is, it can be determined that the measurement threshold value 2 corresponding to the measurement type of the line width 1 is. If the first measurement data 3 of a certain repeating pattern unit corresponding to the measurement type of the current line width 1 is greater than the measurement threshold 2, it can be determined that the repeating pattern unit or the repeating pattern sub-unit where the first measurement data 3 is located is determined to be an abnormal pattern unit, and the abnormal pattern unit and the first measurement data 3 are stored in an abnormal feature library.

It should be noted that the above-mentioned examples are merely illustrative and should not be construed as a limit for the manner in which the abnormal pattern units are determined in embodiments of the present application.

In step 308, the isolated pattern sub-unit is matched with the abnormal pattern units in the abnormal feature library to determine the degree of matching.

In step 309, whether the isolated pattern sub-unit has a defect is determined based on the degree of matching.

A large number of abnormal pattern units and the measurement data corresponding to each of the abnormal pattern units can be stored in the abnormal feature library. Thus, the isolated pattern sub-unit may be obtained after the non-repeating unit is segmented, the isolated pattern sub-unit may be matched with the abnormal pattern unit to determine the degree of matching of them, and then it may be determined whether the isolated pattern sub-unit has a defect based on the degree of matching.

It will be appreciated that there may be many ways of determining the degree of matching between the isolated pattern sub-units and the abnormal pattern units. For example, the isolated pattern sub-units and the abnormal pattern units may be aligned to determine the degree of matching between the isolated pattern sub-units and the abnormal pattern units according to the size, shape, outline, position, etc., of each of the isolated pattern sub-units and each of the abnormal pattern units, which is not limited in the present application.

Optionally, when the degree of matching of a certain isolated pattern unit is greater than a certain threshold value, it can be determined that the isolated pattern unit has a defect, etc. which is not limited in the present application.

Optionally, the isolated pattern sub-unit may be measured to obtain third measurement data, which may then be compared with the measurement data of each of the abnormal patterns in the abnormal feature library to determine whether the isolated pattern sub-unit has a defect.

It should be noted that the above-mentioned examples are merely illustrative and should not be construed as a limit for the manner in which the abnormal pattern units are determined in the embodiments of the present application.

In the embodiments of the present application, a repeating pattern unit and a non-repeating pattern unit in a SEM image can be determined based on the SEM image to be detected and a pattern unit in a design layout. Then the non-repeating pattern unit can be segmented to obtain a repeating pattern sub-unit and an isolated pattern sub-unit, and measurement points can be set in the repeating pattern unit and the repeating pattern sub-unit to determine first measurement data. Then, the measurement points can be set in the same position of a target pattern unit corresponding to the design layout to determine second measurement data, and difference information can be determined based on the first measurement data and the second measurement data. Then, a mean value and a standard deviation corresponding to the measurement type is determined on the basis of the measurement type of the first measurement data and the second measurement data corresponding to the difference information. Then whether the repeating pattern unit or the repeating pattern sub-unit has a defect is determined on the basis of each of the first measurement data, the corresponding mean value, and standard deviation corresponding to the measurement type, and the isolated pattern sub-unit is matched the abnormal pattern unit in the abnormal feature library to determine a degree of matching. Then, whether the isolated pattern sub-unit has a defect is determined on the basis of the degree of matching. Therefore, in the process of wafer defect detection, the SEM image and the pattern units in the design layout can be measured to obtain the difference information which can characterize the SEM image, and then the defect detection is performed on the SEM image based on the difference information. Since the characteristics of the SEM image and the pattern units in the design layout are fully considered in the process of defect detection, the determined difference information can be more comprehensive and reliable, and the accuracy and reliability of the subsequent wafer defect detection are improved.

According to the present application, an apparatus for detecting wafer defects is provided. As shown in FIG. 5, the apparatus includes a first determination module 510, a measurement module 520, and a second determination module 530.

The first determination module 510 is configured to determine a repeating pattern unit and a non-repeating pattern unit in the SEM image based on the SEM image to be detected and the pattern units in the design layout. The measurement module 520 is configured to measure the pattern units in the design layout, the repeating pattern unit, and the non-repeating pattern unit to determine difference information. The second determination module 530 is configured to determine whether the repeating pattern unit and the non-repeating pattern unit have defects based on the difference information.

In some embodiments, the first determination module 510 is specifically configured to process the SEM image to obtain pattern outlines in the SEM image and to match the pattern outlines with the pattern units in the design layout to determine repeating pattern units and non-repeating pattern units in the SEM image.

In some embodiments, the measurement module 520 includes: a segmentation sub-module configured to segment the non-repeating pattern unit to obtain a repeating pattern sub-unit and an isolated pattern unit; a first determination sub-module configured to set measurement points in the repeating pattern unit and the repeating pattern sub-unit to determine first measurement data; a second determination sub-module configured to set the measurement points at the same position of the target pattern unit corresponding to the design layout to determine second measurement data; a third determination sub-module configured to determine difference information based on the first measurement data and the second measurement data.

In some embodiments, the third determination sub-module is configured to determine the difference information corresponding to each of the measurement types based on the measurement type of the first measurement data and the measurement type of the second measurement data.

In some embodiments, the second determination module 530 includes: a fourth determination sub-module configured to determine a mean value and a standard deviation corresponding to the measurement types based on the measurement types of the first measurement data and the second measurement data corresponding to the difference information; a fifth determination sub-module configured to determine whether the repeating pattern unit or the repeating pattern sub-unit has a defect based on each of the first measurement data corresponding to the measurement type, a corresponding mean value, and a corresponding standard deviation.

In some embodiments, the fifth determining sub-module includes: a first determination unit configured to determine a measurement threshold value corresponding to the measurement type based on a mean value and a standard deviation corresponding to the measurement type; a second determination unit configured to determine that the repeating pattern unit or the repeating pattern sub-unit where any one of the first measurement data is located has a defect when any one of the first measurement data is greater than the measurement threshold value of the measurement type; a third determination unit configured to determine a repeating pattern unit or a repeating pattern sub-unit where any one of the first measurement data is located as an abnormal pattern unit, and to store the abnormal pattern units and the any one of the first measurement data into the abnormal feature library.

In some embodiments, the second determination module 530 is specifically configured to match the isolated pattern unit with an abnormal pattern unit in an abnormal feature library to determine a degree of matching, and determine whether the isolated pattern sub-unit has a defect based on the degree of matching.

The apparatus for detecting wafer defects provided in the present application can first determine a repeating pattern unit and a non-repeating pattern unit in a SEM image based on the SEM image to be detected and pattern units in a design layout, and then can measure the pattern unit in the design layout, the repeating pattern unit, and the non-repeating pattern unit to determine difference information, and determine whether the repeating pattern unit and the non-repeating pattern unit have defects based on the difference information. Therefore, in the process of wafer defect detection, the SEM image and the pattern units in the design layout can be measured to obtain the difference information which can characterize the SEM image, and then a defect detection is performed on the SEM image based on the difference information. Since the characteristics of the SEM image and the pattern units in the design layout are fully considered in the process of defect detection, the determined difference information can be more comprehensive and reliable, and the accuracy and reliability of the subsequent wafer defect detection are improved.

It is to be understood that the specific features, operations, and details described herein above with respect to the methods of the present application may also be similarly applied to the apparatuses and systems of the present application, or vice versa. In addition, each of the steps of the method of the present application described above may be performed by a corresponding component or unit of the apparatus or system of the present application.

It should be understood that the various modules/units of the apparatus of the present application may be implemented in whole or in part by software, hardware, firmware, or a combination thereof. Each of the modules/units may be embedded in the processor of the electronic device in hardware or firmware, or may be stored in the memory of the electronic device in software for invocation by the processor to perform the operations of the modules/units. Each module/unit may be implemented as a separate component or module, or two or more modules/units may be implemented as a single component or module.

As shown in FIG. 6, the present application provides an electronic device 600 including a processor 601 and a memory 602 in which computer program instructions are stored. The processor 601, when executing computer program instructions, implements the steps of the above-described method for detecting wafer defects. The electronic device 600 may broadly be a server, a terminal, or any other electronic device having the necessary computing and/or processing capabilities.

In one embodiment, the electronic device 600 may include a processor, a memory, network interface, a communication interface, etc., connected via a system bus. The processor of the electronic device 600 may be used to provide the necessary computing, processing, and/or control capabilities. The memory of the electronic device 600 may include a non-volatile storage medium and an internal memory. The non-volatile storage medium may store an operating system, computer programs, and the like. The internal memory may provide an environment for the operation of an operating system and computer programs in the non-volatile storage medium. The network interface and communication interface of the electronic device 600 may be used to connect and communicate with external devices via a network. The computer program, when executed by a processor, performs the steps of the method of the present application.

The present application provides a computer-readable storage medium storing computer program instructions which implement the above-mentioned method for detecting wafer defects when executed by a processor.

It will be appreciated by those skilled in the art that the method steps of the present application may be performed by a computer program directed to associated hardware, such as the electronic device 600 or a processor, which computer program may be stored in a non-transitory computer readable storage medium and which, when executed, causes the steps of the present application to be performed. Any reference herein to memory, storage, or other media may include non-volatile or volatile memory, as the case may be. Examples of non-volatile memory include read only memory (ROM), programmable ROM (PROM), electrically programmable ROM (EPROM), electrically erasable programmable ROM (EEPROM), flash memory, magnetic tape, floppy disk, magneto-optical data storage device, optical data storage device, hard disk, solid-state disk, and the like. Examples of volatile memory include random access memory (RAM), external cache memory, and the like.

1. A method for detecting wafer defects, comprising:
determining a repeating pattern unit and a non-repeating pattern unit in a Scanning Electron Microscope (SEM) image based on the SEM image to be detected and pattern units in a design layout;
measuring the pattern units in the design layout, the repeating pattern unit, and the non-repeating pattern unit to determine difference information; and
determining whether the repeating pattern unit and the non-repeating pattern unit have defects based on the difference information.

2. The method for detecting wafer defects according to claim 1, wherein the determining a repeating pattern unit and a non-repeating pattern unit in a SEM image based on the SEM image to be detected and pattern units in a design layout comprises:
processing the SEM image to obtain pattern outlines in the SEM image; and
matching the pattern outlines with the pattern units in the design layout to determine the repeating pattern unit and the non-repeating pattern unit in the SEM image.

3. The method for detecting wafer defects according to claim 1, wherein the measuring the pattern units in the design layout, the repeating pattern unit, and the non-repeating pattern unit to determine difference information comprises:
segmenting the non-repeating pattern unit to obtain a repeating pattern sub-unit and an isolated pattern sub-unit;
setting measurement points in the repeating pattern unit and the repeating pattern sub-unit to determine first measurement data;
setting measurement points in corresponding target pattern units of the design layout at the same positions to determine second measurement data; and
determining the difference information based on the first measurement data and the second measurement data.

4. The method for detecting wafer defects according to claim 3, wherein the determining the difference information based on the first measurement data and the second measurement data comprises:
determining the difference information corresponding to each of measurement types based on the measurement type of the first measurement data and the measurement type of the second measurement data.

5. The method for detecting wafer defects according to claim 4, wherein the determining whether the repeating pattern unit and the non-repeating pattern unit have defects based on the difference information comprises:
determining a mean value and a standard deviation corresponding to each of the measurement types based on the measurement type of the first measurement data and the measurement type of the second measurement data corresponding to the difference information; and
determining whether the repeating pattern unit or the repeating pattern sub-unit has a defect based on each of the first measurement data, the mean value, and the standard deviation corresponding to the measurement type.

6. The method for detecting wafer defects according to claim 5, wherein the determining whether the repeating pattern unit or the repeating pattern sub-unit has a defect based on the each of the first measurement data, the mean value, and the standard deviation corresponding to the measurement type comprises:
determining a measurement threshold value corresponding to the measurement type based on the mean value and standard deviation corresponding to the measurement type;
in response to any one of the first measurement data being greater than the measurement threshold value of the measurement type, determining that the repeating pattern unit or the repeating pattern sub-unit where the first measurement data being greater than the measurement threshold value of the measurement type is located has the defect; and
determining the repeating pattern unit or the repeating pattern sub-unit where any one of the first measurement data being greater than the measurement threshold value of the measurement type is located to be an abnormal pattern unit, and storing the abnormal pattern unit and any one of the first measurement data in an abnormal feature library.

7. The method for detecting wafer defects according to claim 3, wherein the determining whether the repeating pattern unit and the non-repeating pattern unit have defects based on the difference information comprises:
matching the isolated pattern sub-unit with an abnormal pattern unit in the abnormal feature library to determine a degree of matching, and
determining whether the isolated pattern sub-unit has a defect based on the degree of matching.

8. An apparatus for detecting wafer defects, comprising:
a first determination module configured to determine a repeating pattern unit and a non-repeating pattern unit in a SEM image based on the SEM image to be detected and pattern units in the design layout;
a measurement module configured to measure pattern units in the design layout, the repeating pattern unit, and the non-repeating pattern unit to determine difference information; and
a second determining module configured to determine whether the repeating pattern unit and the non-repeating pattern unit have defects based on the difference information.

9. An electronic device, comprising:
a processor; and
a memory in which computer program instructions are stored,
wherein the processor implements the method for detecting wafer defects according to claim 1 when executing the computer program instructions.

10. A non-transitory computer-readable storage medium, storing computer program instructions which implement the method for detecting wafer defects according to claim 1 when executed by a processor.
